(19) United States
(12) Patent Application Publication
(10) Pub. No.: US 2025/0318397 A1
(43) Pub. Date: Oct. 9, 2025

(54) DISPLAY DEVICE

(71) Applicant: Samsung Display Co., LTD., Yongin-si (KR)

(72) Inventors: DONG GYU BAECK, Yongin-si (KR); MINSEOK KIM, Yongin-si (KR); Song Yi KIM, Yongin-si (KR); Su Jin KIM, Yongin-si (KR); Myung Jin LEE, Yongin-si (KR); YONGSEOK CHOI, Yongin-si (KR)

(21) Appl. No.: 18/977,656

(22) Filed: Dec. 11, 2024

(30) Foreign Application Priority Data
Apr. 8, 2024 (KR) 10-2024-0047591

(51) Int. Cl. H10K 59/38; H10K 59/80; H10K 102/00

(52) U.S. Cl. CPC H10K 59/38; H10K 59/873; H10K 59/877; H10K 59/8792; H10K 2102/331

(57) ABSTRACT

A display device includes a substrate, a transistor on the substrate, a light emitting element electrically connected to the transistor, an encapsulation layer on the light emitting element, a color conversion layer and a transmission layer on the encapsulation layer, and a partition wall between the color conversion layer and the transmission layer that are adjacent to one another, the partition wall including a first partition wall and a second partition wall having different heights, wherein at least one of the color conversion layer and the transmission layer has a inclined shape in a cross sectional view between the first partition wall and the second partition wall.

### CROSS-REFERENCE TO RELATED APPLICATION

The present application claims priority to and the benefit of Korean Patent Application No. 10-2024-0047591, filed on Apr. 8, 2024, in the Korean Intellectual Property Office, the entire disclosure of which is incorporated herein by reference.

### BACKGROUND

### 1. Field

Aspects of the present disclosure relate to a display device.

### 2. Description of the Related Art

A light emitting element is a device where holes supplied from an anode and electrons supplied from a cathode combine within a light emitting layer formed between the anode and cathode to form excitons, and as these excitons stabilize, light is emitted.

Light emitting elements have various desirable features such as wide viewing angle, fast response speed, thinness, and low power consumption, so they are widely applied to various electrical and electronic devices such as televisions, monitors, and mobile phones.

Recently, a display device including a color conversion layer has been proposed to implement a highly efficient display device. The color conversion layer may convert incident light into a different color.

The above information disclosed in this Background section is only for enhancement of understanding of the background of the invention and therefore it may contain information that does not form the prior art.

### SUMMARY

Aspects of embodiments are directed to a display device that improves color reproduction by reducing external light reflectance.

According to some embodiments of the present disclosure, there is provided a display device including: a substrate; a transistor on the substrate; a light emitting element electrically connected to the transistor; an encapsulation layer on the light emitting element; a color conversion layer and a transmission layer on the encapsulation layer; and a partition wall between the color conversion layer and the transmission layer that are adjacent to one another, the partition wall including a first partition wall and a second partition wall having different heights, wherein at least one of the color conversion layer and the transmission layer has a inclined shape in a cross sectional view between the first partition wall and the second partition wall.

In some embodiments, a height of the first partition wall is greater than a height of the second partition wall.

In some embodiments, the color conversion layer has a first height adjacent to the first partition wall and a second height adjacent to the second partition wall, and wherein the first height is greater than the second height.

In some embodiments, the transmission layer has a first height adjacent to the first partition wall and a second height adjacent to the second partition wall, and the first height is greater than the second height.

In some embodiments, each of the color conversion layer and the transmission layer is between the first partition wall and the second partition wall.

In some embodiments, the first partition wall and the second partition wall are alternately arranged.

In some embodiments, a thickness of the color conversion layer decreases from the first partition wall toward the second partition wall.

In some embodiments, a thickness of the transmission layer decreases from the first partition wall toward the second partition wall.

In some embodiments, the light emitting element includes: a first electrode electrically connected to the transistor; a light emitting layer on the first electrode; and a second electrode on the light emitting layer.

In some embodiments, the color conversion layer includes a quantum dot and a scatterer, and the transmission layer includes a scatterer.

According to some embodiments of the present disclosure, there is provided a display device, including: a substrate; a transistor on the substrate; a light emitting element electrically connected to the transistor; an encapsulation layer on the light emitting element; a color conversion layer and a transmission layer on the encapsulation layer; and a partition wall between the color conversion layer and the transmission layer that are adjacent to one another, the partition wall including a third partition wall and a fourth partition wall, wherein each of the third and fourth partition walls includes a hydrophilic region and a hydrophobic region, and wherein hydrophilic regions in the third partition wall and the fourth partition wall have different heights.

In some embodiments, the third partition wall includes a first region exhibiting hydrophilicity and a second region exhibiting hydrophobicity, wherein the fourth partition wall includes a third region exhibiting hydrophilicity and a fourth region exhibiting hydrophobicity, and wherein a height of the first region is greater than a height of the third region.

In some embodiments, the color conversion layer is at an interface between the first region and the second region.

In some embodiments, the color conversion layer is at an interface between the third region and the fourth region.

In some embodiments, the third partition wall and the fourth partition wall have same height.

In some embodiments, the third partition wall and the fourth partition wall are alternately arranged.

In some embodiments, a thickness of the color conversion layer and a thickness of the transmission layer decrease from the third partition wall toward the fourth partition wall.

In some embodiments, each of the color conversion layer and the transmission layer is between the third partition wall and the fourth partition wall.

In some embodiments, the light emitting element includes: a first electrode electrically connected to the transistor; a light emitting layer on the first electrode; and a second electrode on the light emitting layer.

In some embodiments, the color conversion layer includes a quantum dot and a scatterer, and the transmission layer includes a scatterer.

According to some embodiments, color reproducibility of light provided from the display device may be improved by reducing external light reflectance.

### BRIEF DESCRIPTION OF THE DRAWINGS

FIG. 1 is a schematic perspective view of a display device according to some embodiments of the present disclosure.

FIG. 2 is a schematic cross-sectional view of a display device according to some embodiments of the present disclosure.

FIG. 3 is a cross-sectional view of a display device according to some embodiments of the present disclosure.

FIG. 4 is a diagram showing a path along which light moves in a partial area of a display device according to some embodiments of the present disclosure.

FIGS. 5, 6, 7, 8, and 9 are cross-sectional views of a display device according to some other embodiments of the present disclosure.

### DETAILED DESCRIPTION

Hereinafter, with reference to the attached drawings, various embodiments of the present disclosure will be described in detail so that those skilled in the art may easily implement the present disclosure. The invention may be implemented in many different forms and is not limited to the embodiments described herein.

In order to clearly explain the present invention, parts that are not relevant to the description may be omitted, and identical or similar components are assigned the same reference numerals throughout the specification.

In addition, the size and thickness of each component shown in the drawings are arbitrarily shown for convenience of explanation, so the present disclosure is not necessarily limited to that which is shown. In the drawing, the thickness is enlarged to clearly express various layers and regions. And in the drawing, for convenience of explanation, the thickness of some layers and regions are exaggerated.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

It will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value. Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

In addition, throughout the specification, when reference is made to “on a plane,” this means when the target part is viewed from above, and when reference is made to “in a cross-section,” this means when a cross-section of the target portion is cut vertically and viewed from the side.

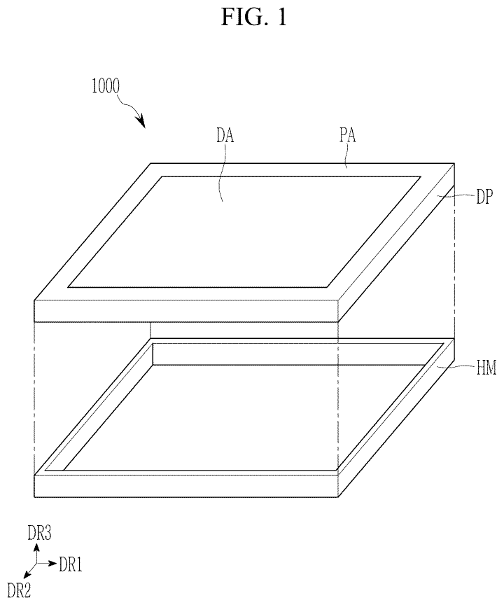

Hereinafter, a display device according to some embodiments will be described with reference to FIG. 1. FIG. 1 is a schematic exploded perspective view of the display device according to some embodiments of the present disclosure.

Referring to FIG. 1, the display device 1000 according to some embodiments may include a display panel DP and a housing HM.

A side (e.g., the front side or front surface) of the display panel DP on which the image is displayed is parallel to the side (e.g., the read side or rear surface) defined by the first direction DR1 and the second direction DR2. The third direction DR3 indicates the normal direction of a side on which the image is displayed, that is, the thickness direction of the display panel DP. The front (or upper) and back (or lower) surfaces of each member are separated by the third direction DR3. However, the directions indicated by the first to third directions DR1, DR2, and DR3 are relative concepts and may be changed to other directions.

The display panel DP may be a flat rigid display panel, but is not limited thereto and may be a flexible display panel. The display panel DP may be made of an organic light emitting display panel. However, the type of display panel DP is not limited to this and may be made of various suitable types of panels. For example, the display panel DP may be made of a liquid crystal display panel, an electrophoretic display panel, an electrowetting display panel, of the like. Additionally, the display panel DP may be made of a next-generation display panel such as a micro light emitting diode display panel, a quantum dot light emitting diode display panel, or a quantum dot organic light emitting diode display panel.

Micro LED display panels are made up of light emitting diodes measuring 10 to 100 micrometers to form each pixel. Because these micro light emitting diode display panels use inorganic materials, the backlight may be omitted, the response speed is fast, high brightness may be achieved with low power, and it does not break when bent.

Quantum dot light emitting diode display panels are made by attaching a layer containing quantum dots or forming them with a material containing quantum dots. Quantum dots are particles made of inorganic materials such as indium and cadmium, they emit light on their own, and have a diameter of several nanometers or less. By controlling the particle size of quantum dots, light of a desired color may be displayed. The quantum dot organic light emitting diode display panel uses a blue organic light emitting diode as a light source and displays color by attaching a layer containing red and green quantum dots on it or depositing a material containing red and green quantum dots. The display panel DP according to some embodiments may be made of various suitable other display panels.

As shown in FIG. 1, the display panel DP includes a display area DA where an image is displayed, and a non-display area PA adjacent to (e.g., surrounding) the display area DA. The non-display area PA is an area where images are not displayed (e.g., cannot be displayed, such as an area lacking light emitting pixels). For example, the display area DA may have a square shape, and the non-display area PA may have a shape surrounding the display area DA. However, the shape of the display area DA and the non-display area PA may be relatively designed (e.g., designed in relation to one another) without being limited thereto.

The housing HM provides a set or predetermined internal space. The display panel DP is mounted inside the housing HM. In addition to the display panel DP, various suitable electronic components, such as a power supply unit, a storage device, and an audio input/output module, may be mounted inside the housing HM.

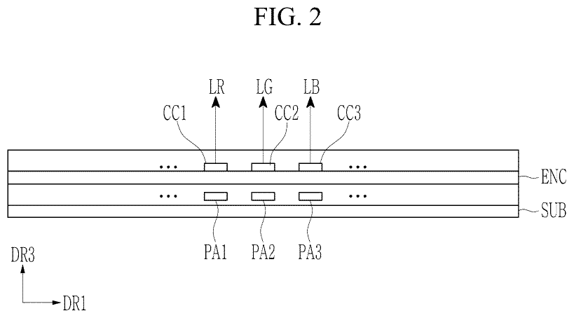

Hereinafter, the display area of the display panel according to some embodiments will be described with reference to FIG. 2. FIG. 2 is a schematic cross-sectional view of a display panel according to some embodiments of the present disclosure.

Referring to FIG. 2, a plurality of pixels PA1, PA2, and PA3 may be disposed on the substrate SUB overlapping the display area DA of FIG. 1. Each pixel PA1, PA2, and PA3 may include a plurality of transistors and a light emitting element connected thereto. In this specification, the shape and arrangement of the plurality of pixels PA1, PA2, and PA3 may be modified in various suitable ways.

An encapsulation layer ENC may be disposed on the plurality of pixels PA1, PA2, and PA3. The display area DA may be protected from external air or moisture through the encapsulation layer ENC. The encapsulation layer ENC may be integrally provided to overlap the entire surface of the display area DA, and may be partially disposed on the non-display area PA.

A first color conversion unit CC1, a second color conversion unit CC2, and a transmission unit CC3 may be disposed on the encapsulation layer ENC. The first color conversion unit CC1 overlaps with the first pixel PA1, the second color conversion unit CC2 overlaps with the second pixel PA2, and the transmission unit CC3 overlaps with the third pixel PA3.

Light emitted from the first pixel PA1 may pass through the first color conversion unit CC1 to provide red light LR. Light emitted from the second pixel PA2 may pass through the second color conversion unit CC2 to provide green light LG. Light emitted from the third pixel PA3 may pass through the transmission part CC3 to provide blue light LB.

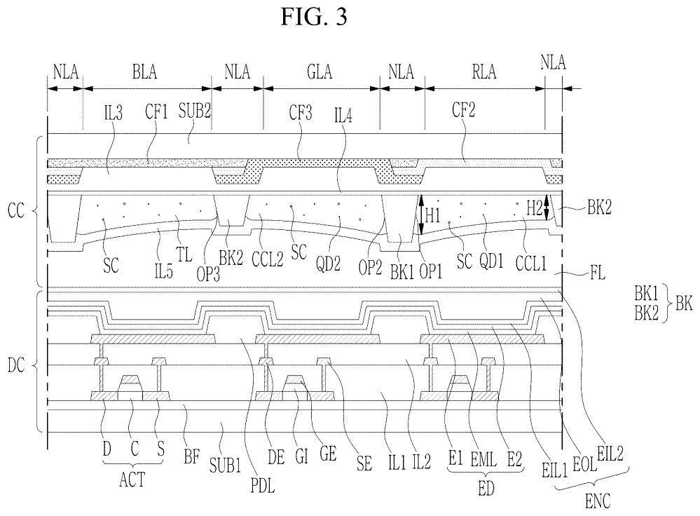

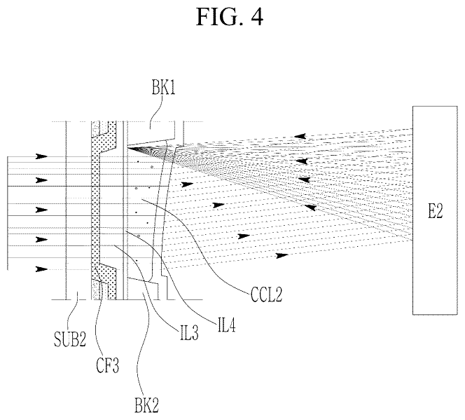

Hereinafter, with reference to FIGS. 3 and 4, a detailed stack structure of a display device according to some embodiments will be further described. FIG. 3 is a cross-sectional view of the display device according to some embodiments of the present disclosure; and FIG. 4 is a diagram showing a path along which light moves in a partial area of the display device according to some embodiments of the present disclosure.

First, referring to FIG. 3, the display area DA of FIG. 1 according to some embodiments includes a red light emitting region RLA, a green light emitting region GLA, and a blue light emitting region BLA. A non-light emitting region NLA may be disposed between the red light emitting region RLA, the green light emitting region GLA, and the blue light emitting region BLA. Each light emitting region may correspond to a pixel. For example, the blue light emitting region BLA, the red light emitting region RLA, and the green light emitting region GLA may correspond to blue pixels, red pixels, and green pixels, respectively. The shape and arrangement of each of the red light emitting region RLA, the green light emitting region GLA, and the blue light emitting region BLA may be modified in various suitable ways.

The display unit DC according to some embodiments includes a first substrate SUB1. The first substrate SUB1 may include a flexible material such as plastic that may bend, fold, or roll.

The buffer layer BF may be disposed on the first substrate SUB1. In some embodiments, the buffer layer BF may be omitted. The buffer layer BF may include a silicon nitride SiNₓ, a silicon oxide SiO₂, a silicon oxynitride, and/or the like. The buffer layer BF is disposed between the first substrate SUB1 and the semiconductor layer ACT, blocking impurities from the first substrate SUB1 during the crystallization process to form polycrystalline silicon, thereby enhancing the characteristics of the polycrystalline silicon, and flattening the first substrate SUB1 to relieve the stress in the semiconductor layer ACT formed on the buffer layer BF.

The semiconductor layer ACT is disposed on the buffer layer BF. The semiconductor layer ACT may be include polycrystalline silicon, an oxide semiconductor, and/or the like. The semiconductor layer ACT includes a channel region C, a source region S, and a drain region D. The source region S and drain region D are respectively arranged on both sides of the channel region C. The channel region C is an intrinsic semiconductor that is not doped with impurities, and the source region S and drain region D are impurity semiconductors that are doped with conductive impurities. The semiconductor layer ACT may include an oxide semiconductor, in which case a separate protective layer may be added to protect the oxide semiconductor material, which is vulnerable to external environments such as high temperature.

A gate insulating layer GI is disposed on the semiconductor layer ACT. The gate insulating layer GI may be a single layer or a multilayer structure including at least one of a silicon nitride SiNₓ, a silicon oxide SiO₂, and a silicon oxynitride.

A gate electrode GE is disposed on the gate insulating layer GI, and the gate electrode GE may be a multilayer layer structure including a metal layer that includes any one of copper (Cu), a copper alloy, aluminum (AI), an aluminum alloy, molybdenum (Mo), and a molybdenum alloy.

An interlayer insulating layer IL1 is disposed on the gate electrode GE and the gate insulating layer GI. The interlayer insulating layer IL1 may include a silicon nitride SiNₓ, a silicon oxide SiO₂, a silicon oxynitride, and/or the like. Openings exposing the source region S and drain region D are disposed in the interlayer insulating layer IL1.

A source electrode SE and a drain electrode DE are disposed on the interlayer insulating layer IL1. The source electrode SE and the drain electrode DE are respectively connected to the source region S and drain region D of the semiconductor layer ACT through openings formed in the interlayer insulating layer IL1.

A passivation layer IL2 is disposed on the interlayer insulating layer IL1, the source electrode SE, and the drain electrode DE. The passivation layer IL2 covers and flattens the interlayer insulating layer IL1, the source electrode SE, and the drain electrode DE, so that the first electrode E1 may be formed on the passivation layer IL2 without steps. This passivation layer IL2 may include an organic material such as polyacrylate resin or polyimide resin, or a laminated layer of an organic material and an inorganic material.

The first electrode E1 is disposed on the passivation layer IL2. The first electrode E1 is connected to the drain electrode DE through an opening in the passivation layer IL2.

A driving transistor including of a gate electrode GE, the semiconductor layer ACT, a source electrode SE, and a drain electrode DE is connected to the first electrode E1 to supply a driving current to the light emitting element ED. The display device according to some embodiments, in addition to the driving transistor shown in FIG. 3, may further include a switching transistor that is connected to a data line and delivers a data voltage in response to a scan signal, and a compensation transistor that is connected to the driving transistor and compensates for the threshold voltage of the driving transistor in response to the scan signal.

A pixel defining layer PDL may be disposed on the protective layer IL2 and the first electrode E1. The pixel defining layer PDL may contain an organic material such as polyacrylate resin or polyimide resin, or a silica-based inorganic material.

The pixel defining layer PDL may have a pixel opening that overlaps the first electrode E1 and defines a light emitting region. The pixel opening may have a planar shape substantially similar to that of the first electrode E1, and may have a diamond or octagonal shape similar to a diamond in a plan view, but is not limited thereto and may have any shape such as a square or polygon.

The light emitting layer EML is disposed on the first electrode E1 overlapping the pixel opening. The light emitting layer EML may be include a low molecular organic material or a high molecular organic material such as PEDOT poly (3,4-ethylenedioxythiophene). In addition, the light emitting layer EML may be a multilayer structure that includes one or more of the a hole injection layer HIL, a hole transport layer HTL, an electron transport layer ETL, and an electron injection layer EIL.

The light emitting layer EML may be disposed mostly within the pixel opening, and according to some embodiments, it may also be disposed on the side or on the pixel defining layer PDL. Although this specification illustrates some embodiments in which the light emitting layer EML continuously overlaps the entire surface of the first substrate SUB1, embodiments of the present disclosure are not limited to this, and some examples in which the light emitting layer EML is disposed only within the opening of the pixel defining layer PDL is also possible.

The second electrode E2 is disposed on the light emitting layer EML. The second electrode E2 may be disposed across a plurality of pixels and may receive a common voltage through a common voltage transmitter in the non-display area.

The first electrode E1, the light emitting layer EML, and the second electrode E2 may form a light emitting element ED. Here, the first electrode E1 may be an anode, which is a hole injection electrode, and the second electrode E2 may be a cathode, which is an electron injection electrode. However, embodiments of the present disclosure are not necessarily limited to this, and the first electrode E1 may be a cathode and the second electrode E2 may be an anode depending on the driving method of the organic light emitting display device.

Holes and electrons are injected into the light emitting layer EML from the first electrode E1 and the second electrode E2, and light emission occurs when the exciton that is a combination of the injected holes and electrons falls from an excited state to the ground state.

The light emitting element ED according to some embodiments may include a plurality of light emitting units. Each light emitting unit may include a light emitting layer. The light emitting element ED according to some embodiments may include a plurality of light emitting layers. The light emitting element ED may be a tandem structure light emitting element. A plurality of light emitting layers may emit the same light or different light. As an example, the light emitting element ED may emit light that is a mixture of green light and blue light, or may emit blue light.

An encapsulation layer ENC is disposed on the second electrode E2. The encapsulation layer ENC may seal the display layer by covering not only the top surface but also the side surfaces of the display layer including the light emitting element ED.

Because the light emitting element is very vulnerable to moisture and oxygen, the encapsulation layer ENC seals the display layer and blocks the inflow of external moisture and oxygen. The encapsulation layer ENC may include multiple layers, and may be formed as a composite layer that includes both an inorganic layer and an organic layer, and may be formed as a triple layer structure sequentially including a first inorganic layer EIL1, an organic layer EOL, and a second inorganic layer EIL2.

The color conversion unit CC is disposed on the encapsulation layer ENC.

The color conversion unit CC includes a second substrate SUB2 that overlaps the first substrate SUB1. The second substrate SUB2 may include a flexible material such as plastic that may bend, fold, or roll easily, or may include a rigid material.

The color conversion unit CC includes a first color filter CF1, a second color filter CF2, and a third color filter CF3 disposed between the second substrate SUB2 and the display unit DC.

The first color filter CF1 may overlap the transmission layer TL. The first color filter CF1 may transmit blue light that has passed through the transmission layer TL and absorb light of the remaining wavelengths, thereby increasing the purity of blue light emitted to the outside of the display device.

The second color filter CF2 may overlap the first color conversion layer CCL1. The second color filter CF2 may transmit red light that has passed through the first color conversion layer CCL1 and absorb light of the remaining wavelengths, thereby increasing the purity of red light emitted to the outside of the display device.

The third color filter CF3 may overlap the second color conversion layer CCL2. The third color filter CF3 may transmit green light that has passed through the second color conversion layer CCL2 and absorb light of the remaining wavelengths, thereby increasing the purity of green light emitted to the outside of the display device.

At least two of the third color filter CF3, the second color filter CF2, and the first color filter CF1 may overlap in the non-light emitting region NLA and serve as a light blocking layer. The non-light emitting region NLA may overlap the pixel defining layer PDL of the display unit DC and the partition wall BK of the color conversion unit CC.

A third insulating layer IL3 and a fourth insulating layer IL4 may be disposed between the color filters CF1, CF2, and CF3 and the display unit DC. For example, the third insulating layer IL3 may include an organic material or an inorganic material such as a silicon nitride SiNₓ, a silicon oxide SiO₂, or a silicon oxynitride. The third insulating layer IL3 may have a relatively low refractive index.

A fourth insulating layer IL4 may be disposed between the third insulating layer IL3 and the display unit DC. The fourth insulating layer IL4 may include an inorganic material such as a silicon nitride SiNₓ, a silicon oxide SiO₂, or a silicon oxynitride. The fourth insulating layer IL4 may be formed through a deposition process, in some embodiments.

A partition wall BK may be disposed between the fourth insulating layer IL4 and the display unit DC. The partition wall BK may include a first opening OP1, a second opening OP2, and a third opening OP3 that overlap the pixel opening. The sizes of the first opening OP1, the second opening OP2, and the third opening OP3 may be different or the same.

The first color conversion layer CCL1 may be disposed within the first opening OP1. In the space divided by the partition wall BK, the first color conversion layer CCL1 may be disposed in the area corresponding to the red light emitting area RLA.

The first color conversion layer CCL1 may convert supplied light into red. The first color conversion layer CCL1 may include a first quantum dot QD1 and a scatterer SC.

The second color conversion layer CCL2 may be disposed within the second opening OP2. In the space partitioned by the partition wall BK, the second color conversion layer CCL2 may be disposed in the area corresponding to the green light emitting area GLA.

The second color conversion layer CCL2 may convert supplied light into green. The second color conversion layer CCL2 may include a second quantum dot QD2 and a scatterer SC.

The transmission layer TL may be disposed within the third opening OP3.

In the space divided by the partition wall BK, the transmission layer TL may be disposed in the area corresponding to the blue light emitting region BLA. The transmission layer TL may transmit light incident from the light emitting element ED.

The transmission layer TL may include a scatterer SC.

The scatterer SC may be one or more selected from the group consisting of SiO₂, BaSO₄, Al₂O₃, ZnO, ZrO₂, and TiO₂.

Then, the quantum dots including the first quantum dot QD1 and the second quantum dot QD2 will be described in further detail below.

In this specification, quantum dots (hereinafter, also referred to as semiconductor nanocrystals) may include Group II-VI compounds, Group III-V compounds, Group IV-VI compounds, Group IV elements or compounds, Group I-III-VI compounds, Group II-III-VI compounds, Group I-II-IV-VI compounds, or combinations thereof.

The Group II-VI compounds include binary compounds selected from the group consisting of CdSe, CdTe, ZnS, ZnSe, ZnTe, ZnO, HgS, HgSe, HgTe, MgSe, MgS, and mixtures thereof; ternary compounds selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and a tetraelement compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The Group II-VI compound may further include a Group III metal.

The Group III-V compounds are binary compounds selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAS, AlPSb, InGaP, InNP, InNAs, InNSb, InPAs, InZnP, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. The Group III-V compound may further include a Group II metal (e.g., InZnP).

The Group IV-VI compounds include binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and quaternary compounds selected from the group consisting of SnPbSSe, SnPbSeTe, SnPbSTe, and mixtures thereof.

The Group IV element or compound is a monoelement compound selected from the group consisting of Si, Ge, and combinations thereof; and a binary compound selected from the group consisting of SiC, SiGe, and combinations thereof, but is not limited thereto.

Examples of the Group I-III-VI compounds include, but are not limited to, CuInSe₂, CuInS₂, CuInGaSe, and CuInGaS. Examples of the Group I-II-IV-VI compounds include, but are not limited to, CuZnSnSe, and CuZnSnS. The Group IV element or compound is a single element selected from the group consisting of Si, Ge, and mixtures thereof; and a binary compound selected from the group consisting of SiC, SiGe, and mixtures thereof.

The Group II-III-VI compounds may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and combinations thereof, but are not limited to these.

The Group I-II-IV-VI compound may be selected from CuZnSnSe and CuZnSnS, but is not limited thereto.

In some embodiments, the quantum dots may not include cadmium. Quantum dots may include semiconductor nanocrystals based on Group III-V compounds including indium and phosphorus. The Group III-V compound may further include zinc. Quantum dots may include semiconductor nanocrystals based on Group II-VI compounds including chalcogen elements (e.g., sulfur, selenium, tellurium, or combinations thereof), and zinc.

In quantum dots, the above-mentioned di-element compound, tri-element compound, and/or quaternary compound may exist in the particle at a uniform concentration, or may exist in the same particle with the concentration distribution partially divided into different states. Additionally, one quantum dot may have a core/shell structure surrounding other quantum dots. The interface between the core and the shell may have a concentration gradient in which the concentration of elements present in the shell decreases toward the center.

In some embodiments, quantum dots may have a core-shell structure including a core containing the above-described nanocrystals and a shell surrounding the core. The shell of the quantum dot may serve as a protective layer to maintain semiconductor properties by preventing chemical denaturation of the core and/or as a charging layer to impart electrophoretic properties to the quantum dot. The shell may be single- or multi-layered. The interface between the core and the shell may have a concentration gradient in which the concentration of elements present in the shell decreases toward the center. Examples of the shell of the quantum dot include metal or non-metal oxides, semiconductor compounds, or combinations thereof.

For example, the oxide of the metal or non-metal is a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or MgAl₂O₄, CoFe₂O₄, NiFe₂O₄, CoMn₂O₄, etc., but the present disclosure is not limited thereto.

In addition, the semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. However, the present disclosure is not limited thereto.

The interface between the core and the shell may have a concentration gradient in which the concentration of elements present in the shell decreases toward the center. Additionally, the semiconductor nanocrystal may have a structure including a single semiconductor nanocrystal core and a multi-layered shell surrounding it. In some embodiments, the multilayer shell may have two or more layers, such as 2, 3, 4, 5, or more layers. The two adjacent layers of the shell may have a single composition or different compositions. In a multilayer shell, each layer may have a composition that changes along the radius.

Quantum dots may have a full width at half maximum FWHM of the emission wavelength spectrum of about 45 nm or less, preferably about 40 nm or less, more preferably about 30 nm or less, and within this range, color purity or color reproducibility may be improved. Additionally, because the light emitted through these quantum dots is emitted in all directions, the optical viewing angle may be improved (e.g., increased).

The quantum dots may have different energy band gaps between the shell material and the core material. For example, the energy band gap of the shell material may be larger than that of the core material. In some other embodiments, the energy band gap of the shell material may be smaller than that of the core material. The quantum dots may have a multilayer shell. In a multilayer shell, the energy band gap of the outer layer may be larger than that of the inner layer (i.e., the layer close to the core). In a multilayer shell, the energy band gap of the outer layer may be smaller than that of the inner layer.

Quantum dots may control absorption/light emitting wavelengths by adjusting their composition and size. The maximum emission peak wavelength of the quantum dot may range from ultraviolet to infrared wavelengths or longer.

Quantum dots may have quantum efficiency of at least about 10%, such as at least about 30%, at least about 50%, at least about 60%, at least about 70%, at least about 90%, or even about 100%. Quantum dots may have a relatively narrow spectrum. The quantum dots may have a full width at half maximum of the emission wavelength spectrum, for example, about 50 nm or less, such as about 45 nm or less, about 40 nm or less, or about 30 nm or less.

The quantum dots may have a particle size of about 1 nm or more or about 100 nm or less. The size of a particle refers to the diameter of the particle or the diameter converted by assuming a spherical shape from a two-dimensional image obtained by transmission electron microscopy analysis. The quantum dots may have a size of about 1 nm to about 20 nm, for example, 2 nm or more, 3 nm or more, or 4 nm or more, or may have a size less than 50 nm, less than 40 nm, less than 30 nm, less than 20 nm, less than 15 nm, or less than 10 nm. The shape of the quantum dot is not particularly limited. For example, the shape of the quantum dot may include, but is not limited to, a sphere, polyhedron, pyramid, multipod, square, cuboid, nanotube, nanorod, nanowire, nanosheet, or a combination thereof.

Quantum dots are commercially available or may be appropriately synthesized. The particle size of quantum dots may be controlled relatively freely during colloid synthesis, and the particle size may also be adjusted uniformly.

Quantum dots may include organic ligands (e.g., having hydrophobic and/or hydrophilic moieties). The organic ligand residue may be bound to the surface of the quantum dot. The organic ligand includes RCOOH, RNH₂, R₂NH, R₃N, RSH, R₃PO, RsP, ROH, RCOOR, RPO(OH)₂, RHPOOH, R₂POOH, or combinations thereof, where R independently represents a C3 to C40 substituted or unsubstituted aliphatic hydrocarbon group (e.g., C5 or more and C24 or less), a substituted or unsubstituted alkene group, a C6 to C40 substituted or unsubstituted aromatic hydrocarbon group (e.g., C6 or more and C20 or less), a C6 to C40 substituted or unsubstituted aryl group, or combinations thereof.

Examples of the organic ligands include thiol compounds such as methane thiol, ethane thiol, propane thiol, butane thiol, pentane thiol, hexane thiol, octane thiol, dodecane thiol, hexadecane thiol, octadecane thiol, and benzyl thiol; amine compounds such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, and trioctylamine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, and trioctyl phosphine; phosphine oxide compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and trioctyl phosphine oxide; diphenyl phosphine; triphenyl phosphine compounds or their oxide compounds; hexylphosphinic acid, octylphosphinic acid, dodecylphosphinic acid, tetradecylphosphinic acid, hexadecylphosphinic acid, octadecylphosphinic acid, and other alkylphosphinic acids; and C5 to C20 alkylphosphonic acids; however, embodiments of the present disclosure are not limited to the aforementioned examples.

Quantum dots may include hydrophobic organic ligands alone or in a mixture of one or more types. The hydrophobic organic ligand may not contain a photopolymerizable residue (e.g., an acrylate group, a methacrylate group, etc.).

The partition wall BK according to some embodiments may include a first partition wall BK1 and a second partition wall BK2. The first partition wall BK1 and the second partition wall BK2 may have different heights. For example, the height of the first partition wall BK1 may be greater than the height of the second partition wall BK2. The first partition wall BK1 and the second partition wall BK2 may be manufactured to have different heights using a halftone mask or the like.

The first and second partition walls BK1 and BK2 may have various suitable arrangements, and as shown in FIG. 3, the first and second partition walls BK1 and BK2 may be alternately arranged.

The first partition wall BK1 and the second partition wall BK2 may include the same or substantially the same material. Additionally, a surface of the first partition wall BK1 and the second partition wall BK2 may have hydrophobicity. A side of the first partition wall BK1 and the second partition wall BK2 facing the display part DC is hydrophobic, and the ink provided in the process of forming the first color conversion layer CCL1, the second color conversion layer CCL2, and the transmission layer TL may be stably injected into the openings OP1, OP2, and OP3 due to the hydrophobicity of the partition walls BK1 and BK2.

The first color conversion layer CCL1 may have an inclined shape in a cross-section. The first color conversion layer CCL1 may have a shape inclined in a direction. Additionally, the first color conversion layer CCL1 may be slightly depressed at a portion in contact with the partition walls BK1, BK2. Additionally, in some embodiments, the first color conversion layer CCL1 may be convexly inclined or concavely inclined in its cross-section.

The first color conversion layer CCL1 may have a first height H1 at a portion adjacent to the first partition wall BK1 and a second height H2 at a portion adjacent to 1 the second partition wall BK2. The first height H1 may be greater than the second height H2.

The second color conversion layer CCL2 may have an inclined shape in a cross-section. The second color conversion layer CCL2 may have a shape inclined in one direction. Additionally, the second color conversion layer CCL2 may be slightly depressed at a portion in contact with the partition walls BK1 and BK2. Additionally, in some embodiments, the second color conversion layer CCL2 may be convexly inclined or concavely inclined in its cross-section.

The second color conversion layer CCL2 may have a first height H1 at a portion adjacent to the first partition wall BK1 and a second height H2 at a portion adjacent to the second partition wall BK2. The first height H1 may be greater than the second height H2.

The transmission layer TL may have an inclined shape in a cross-section. The transmission layer TL may have a shape inclined in a direction. Additionally, the transmission layer TL may be slightly depressed at the portion in contact with the partition walls BK1 and BK2. Additionally, in some embodiments, the transmission layer TL may be convexly inclined or concavely inclined in its cross-section.

The transmission layer TL may have a first height H1 at a portion adjacent to the first partition wall BK1 and a second height H2 at a portion adjacent to the second partition wall BK2. The first height H1 may be greater than the second height H2.

This specification illustrates some embodiments where the first color conversion layer CCL1, the second color conversion layer CCL2, and the transmission layer TL all have an inclined shape, and according to some embodiments, at least one of the first color conversion layer CCL1, the second color conversion layer CCL2, and the transmission layer TL may have an inclined shape.

Referring to FIG. 4, external light incident from the outside of the second substrate SUB2 may pass through the color conversion layers CCL1 and CCL2 or the transmission layer TL to reach the second electrode E2. At this time, light incident 1 from the outside may be refracted by the inclined color conversion layers CCL1 and CCL2 or the transmission layer TL toward the thicker part of the color conversion layers CCL1 and CCL2 or the transmission layer TL. Light refracted in this way may be reflected from the second electrode E2 and be incident on a portion adjacent to the first partition wall BK1. Light reflected from external light may not be emitted to the outside of the display device. Accordingly, the external light reflection effect may be reduced by about 70% to about 80%, and thus the color gamut of light provided from the display device may be improved.

A fifth insulating layer IL5 may be disposed between the partition wall BK, the first color conversion layer CCL1, the second color conversion layer CCL2, the transmission layer TL, and the display unit DC. The fifth insulating layer IL5 may protect the first color conversion layer CCL1, the second color conversion layer CCL2, and the transmission layer TL.

A filling layer FL may be disposed between the fifth insulating layer IL5 and the display unit DC. The filling layer FL may combine components formed on the first substrate SUB1 and components formed on the second substrate SUB2. The first substrate SUB1 and the second substrate SUB2 may be combined by the filling layer FL.

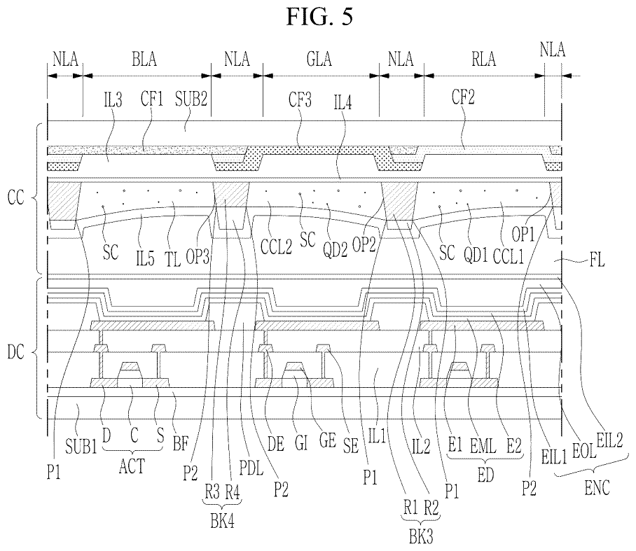

Hereinafter, a display device according to some other embodiments will be described with reference to FIGS. 5 to 9. FIGS. 5 to 9 are cross-sectional views of the display device according to some other embodiments of the present disclosure. Descriptions of components that are the same as those described above may be omitted.

First, referring to FIG. 5, the plurality of partition walls BK3 and BK4 according to some embodiments may have the same height. The plurality of partition walls BK3 and BK4 disposed in the non-light emitting region NLA may be formed to have substantially the same height.

The partition walls BK3 and BK4 according to some embodiments may include a third partition wall BK3 and a fourth partition wall BK4. The third partition wall BK3 and the fourth partition wall BK4 may be alternately arranged as shown in FIG. 5, but are not limited thereto and may be arranged in various suitable repeating forms.

The third partition wall BK3 may include a hydrophilic first region R1 and a hydrophobic second region R2. The second region R2 may be in contact with the first region R1 and may be disposed closer to the display unit DC. The height of the first region R1 may be greater than the height of the second region R2. The second region R2 according to some embodiments may represent the upper surface of the third partition wall BK3.

The fourth partition wall BK4 may include a hydrophilic third region R3 and a hydrophobic fourth region R4. The fourth region R4 may be in contact with the third region R3 and may be disposed closer to the display unit DC. The height of the third region R3 and the height of the fourth region R4 may each be adjusted as desired. The height of the third region R3 may be smaller than the height of the first region R1.

The third partition wall BK3 and the fourth partition wall BK4 may be manufactured from substantially the same material, and the height of the interface where phase separation between the hydrophobic region and the hydrophilic region occurs may be controlled by controlling the temperature of the manufacturing process.

The first color conversion layer CCL1 disposed in the first opening OP1 may include a first portion P1 having a first height and a second portion P2 having a second height. The first height may be greater than the second height. The first portion P1 having a first height may be disposed on an interface between the first region R1 and the second region R2. The second portion P2 having a second height may be disposed on the interface between the third region R3 and the fourth region R4.

The first color conversion layer CCL1 may have an inclined shape in a cross-section. The first color conversion layer CCL1 may have a shape inclined in a direction. Additionally, the first color conversion layer CCL1 may be slightly depressed 1 at a portion that contacts the partition walls BK1 and BK2. Additionally, in some embodiments, the first color conversion layer CCL1 may be convexly inclined or concavely inclined in its cross-section.

The second color conversion layer CCL2 disposed in the second opening OP2 may include a first portion P1 having a first height and a second portion P2 having a second height. The first height may be greater than the second height. The first portion P1 having a first height may be disposed on an interface between the first region R1 and the second region R2. The second portion P2 having a second height may be disposed on the interface between the third region R3 and the fourth region R4.

The second color conversion layer CCL2 may have an inclined shape in a cross-section. The second color conversion layer CCL2 may have a shape inclined in a direction. Additionally, the second color conversion layer CCL2 may be slightly depressed at the portion where it contacts the partition walls BK1 and BK2. Additionally, in some embodiments, the second color conversion layer CCL2 may be convexly inclined or concavely inclined in its cross-section.

The transmission layer TL disposed in the third opening OP3 may include a first portion P1 having a first height and a second portion P2 having a second height. The first height may be greater than the second height. The first portion P1 having a first height may be disposed on an interface between the first region R1 and the second region R2. The second portion P2 having a second height may be disposed on the interface between the third region R3 and the fourth region R4.

The transmission layer TL may have an inclined shape in a cross-section. The transmission layer TL may have a shape inclined in a direction. Additionally, the transmission layer TL may be slightly depressed at the portion in contact with the partition walls BK1 and BK2. Additionally, in some embodiments, the transmission layer TL may be convexly inclined or concavely inclined in its cross-section.

This specification illustrates some embodiments in which the first color conversion layer CCL1, the second color conversion layer CCL2, and the transmission layer TL all have an inclined shape, and according to some embodiments, at least one of the first color conversion layer CCL1, the second color conversion layer CCL2, and the transmission layer TL may have an inclined shape.

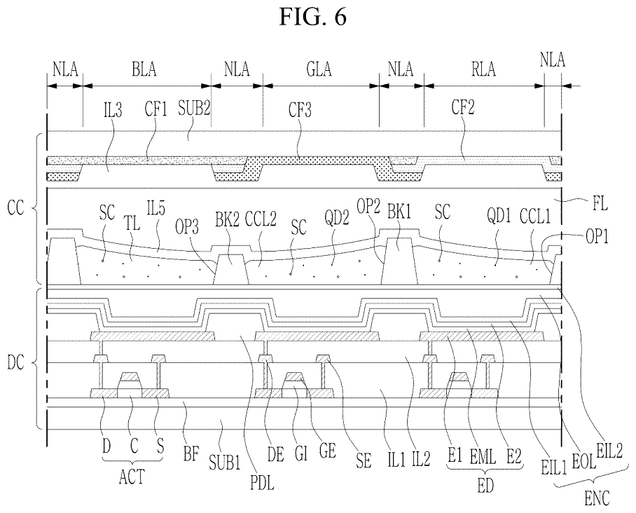

Referring to FIG. 6, the partition wall BK, the first color conversion layer CCL1, the second color conversion layer CCL2, and the transmission layer TL according to some embodiments are disposed on the encapsulation layer ENC. The fifth insulating layer IL5 may be disposed on the partition wall BK, the first color conversion layer CCL1, the second color conversion layer CCL2, and the transmission layer TL. A filling layer FL may be disposed on the fifth insulating layer IL5. The filling layer FL may combine components stacked on the first substrate SUB1 and components stacked on the second substrate SUB2.

As described in FIG. 3, a first color filter CF1, a second color filter CF2, and a third color filter CF3 may be disposed between the filling layer FL and the second substrate SUB2. A third insulating layer IL3 may be disposed between the color filters CF1, CF2, and CF3 and the filling layer FL.

The description of components other than these may be omitted to avoid repeating the description of components of FIG. 3.

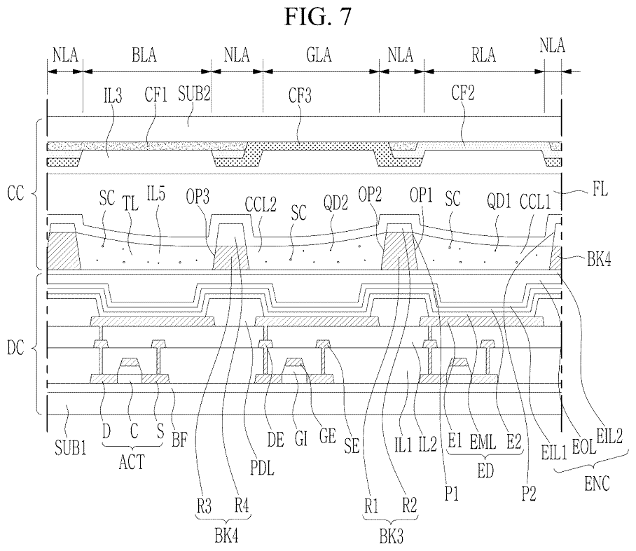

Referring to FIG. 7, the partition wall BK, the first color conversion layer CCL1, the second color conversion layer CCL2, and the transmission layer TL according to some embodiments are disposed on the encapsulation layer ENC.

The fifth insulating layer IL5 may be disposed on the partition wall BK, the first color conversion layer CCL1, the second color conversion layer CCL2, and the transmission layer TL. A filling layer FL may be disposed on the fifth insulating layer IL5. The filling layer FL may combine components stacked on the first substrate SUB1 and components stacked on the second substrate SUB2.

As described in FIG. 3, a first color filter CF1, a second color filter CF2, and a third color filter CF3 may be disposed between the filling layer FL and the second substrate SUB2. A third insulating layer IL3 may be disposed between the color filters CF1, CF2, and CF3 and the filling layer FL.

The description of components other than these may be omitted to avoid repeating the description of components of FIG. 5.

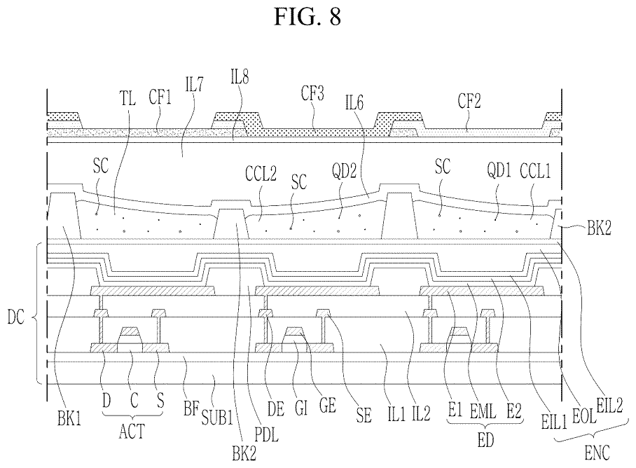

Next, referring to FIG. 8, the partition wall BK, the first color conversion layer CCL1, the second color conversion layer CCL2, and the transmission layer TL according to some embodiments are disposed on the encapsulation layer ENC.

On the partition wall BK, the first color conversion layer CCL1, the second color conversion layer CCL2, the transmission layer TL, the sixth insulating layer IL6, the seventh insulating layer IL7, and the eighth insulating layer IL8 may be sequentially disposed.

Each of the sixth insulating layer IL6, the seventh insulating layer IL7, and the eighth insulating layer IL8 may independently include an organic material or an inorganic material.

A first color filter CF1, a second color filter CF2, and a third color filter CF3 may be disposed on the eighth insulating layer IL8. The description of Components other than these will may be omitted to avoid repeating the description of components of FIG. 3.

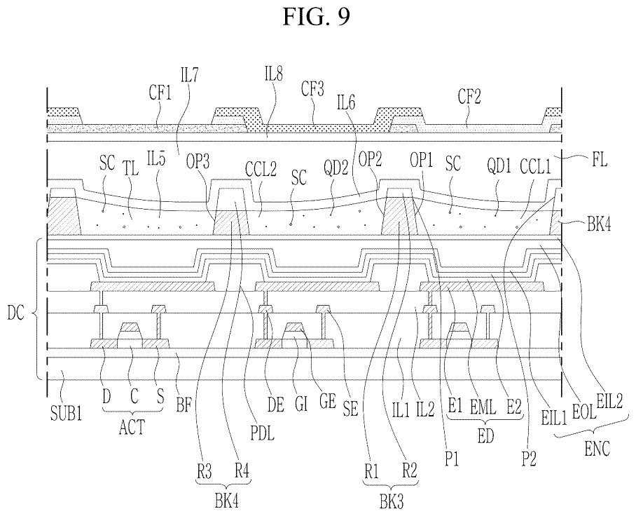

Referring to the following FIG. 9, according to some embodiments, the partition wall BK, the first color conversion layer CCL1, the second color conversion layer CCL2, and the transmission layer TL may be disposed on the encapsulation layer ENC.

On the partition wall BK, the first color conversion layer CCL1, the second color conversion layer CCL2, the transmission layer TL, the sixth insulating layer IL6, the seventh insulating layer IL7, and the eighth insulating layer IL8 may be sequentially disposed. Each of the sixth insulating layer IL6, the seventh insulating layer IL7, and the eighth insulating layer IL8 may independently include an organic material or an inorganic material.

A first color filter CF1, a second color filter CF2, and a third color filter CF3 may be disposed on the eighth insulating layer IL8. The description of components other than these may be omitted to avoid repeating the description of components of FIG. 5.

According to the described embodiments, light entering from the outside is refracted by the color conversion layers CCL1 and CCL2 or and transmission layer TL, and the light refracted in this way may be reflected at the second electrode E2 and directed toward the area adjacent to the partition wall, that is, into the non-light emitting region. Accordingly, the external light reflection effect may be reduced, and the color gamut of light provided from the display device may be improved.

Although the embodiments of the present disclosure have been described in detail above, the scope of the present invention is not limited thereto, and various suitable modifications and improvements made by those skilled in the art using the basic concepts of the present disclosure defined in the following claims are also possible.

### DESCRIPTION OF SOME OF THE SYMBOLS

SUB1, SUB2: substrate
ED: light emitting element
CCL1, CCL2: color conversion layer
TL: transmission layer
BK1: first partition wall
BK2: second partition wall
BK3: third partition wall
BK4: fourth partition wall

What is claimed is:

1. A display device comprising:
a substrate;
a transistor on the substrate;
a light emitting element electrically connected to the transistor;
an encapsulation layer on the light emitting element;
a color conversion layer and a transmission layer on the encapsulation layer; and
a partition wall between the color conversion layer and the transmission layer that are adjacent to one another, the partition wall comprising a first partition wall and a second partition wall having different heights,
wherein at least one of the color conversion layer and the transmission layer has a inclined shape in a cross sectional view between the first partition wall and the second partition wall.

2. The display device of claim 1, wherein a height of the first partition wall is greater than a height of the second partition wall.

3. The display device of claim 2, wherein the color conversion layer has a first height adjacent to the first partition wall and a second height adjacent to the second partition wall, and
wherein the first height is greater than the second height.

4. The display device of claim 2, wherein the transmission layer has a first height adjacent to the first partition wall and a second height adjacent to the second partition wall, and
wherein the first height is greater than the second height.

5. The display device of claim 1, wherein each of the color conversion layer and the transmission layer is between the first partition wall and the second partition wall.

6. The display device of claim 5, wherein the first partition wall and the second partition wall are alternately arranged.

7. The display device of claim 1, wherein a thickness of the color conversion layer decreases from the first partition wall toward the second partition wall.

8. The display device of claim 1, wherein a thickness of the transmission layer decreases from the first partition wall toward the second partition wall.

9. The display device of claim 1, wherein the light emitting element comprises:
a first electrode electrically connected to the transistor;
a light emitting layer on the first electrode; and
a second electrode on the light emitting layer.

10. The display device of claim 1, wherein the color conversion layer comprises a quantum dot and a scatterer, and
wherein the transmission layer comprises a scatterer.

11. A display device comprising:
a substrate;
a transistor on the substrate;
a light emitting element electrically connected to the transistor;
an encapsulation layer on the light emitting element;
a color conversion layer and a transmission layer on the encapsulation layer; and
a partition wall between the color conversion layer and the transmission layer that are adjacent to one another, the partition wall comprising a third partition wall and a fourth partition wall,
wherein each of the third and fourth partition walls comprises a hydrophilic region and a hydrophobic region, and
wherein hydrophilic regions in the third partition wall and the fourth partition wall have different heights.

12. The display device of claim 11, wherein the third partition wall comprises a first region exhibiting hydrophilicity and a second region exhibiting hydrophobicity,
wherein the fourth partition wall comprises a third region exhibiting hydrophilicity and a fourth region exhibiting hydrophobicity, and
wherein a height of the first region is greater than a height of the third region.

13. The display device of claim 12, wherein the color conversion layer is at an interface between the first region and the second region.

14. The display device of claim 13, wherein the color conversion layer is at an interface between the third region and the fourth region.

15. The display device of claim 11, wherein the third partition wall and the fourth partition wall have same height.

16. The display device of claim 11, wherein the third partition wall and the fourth partition wall are alternately arranged.

17. The display device of claim 11, wherein a thickness of the color conversion layer and a thickness of the transmission layer decrease from the third partition wall toward the fourth partition wall.

18. The display device of claim 11, wherein each of the color conversion layer and the transmission layer is between the third partition wall and the fourth partition wall.

19. The display device of claim 11, wherein the light emitting element comprises:
a first electrode electrically connected to the transistor;
a light emitting layer on the first electrode; and
a second electrode on the light emitting layer.

20. The display device of claim 11, wherein the color conversion layer comprises a quantum dot and a scatterer, and
wherein the transmission layer comprises a scatterer.
